(19) United States
(12) Patent Application Publication
(10) Pub. No.: US 2018/0178207 A1
(43) Pub. Date: Jun. 28, 2018

(54) IN-SITU GROWTH AND CATALYTIC NANOPARTICLE DECORATION OF METAL OXIDE NANOWIRES

(71) Applicant: OKINAWA INSTITUTE OF SCIENCE AND TECHNOLOGY SCHOOL CORPORATION, Okinawa (JP)

(72) Inventors: Stephan STEINHAUER, Stockholm (SE); Vidya Dhar SINGH, Okinawa (JP); Mukhles Ibrahim SOWWAN, Okinawa (JP)

(73) Assignee: OKINAWA INSTITUTE OF SCIENCE AND TECHNOLOGY SCHOOL CORPORATION, Okinawa (JP)

(21) Appl. No.: 15/754,091

(22) PCT Filed: Aug. 18, 2016
(86) PCT No.: PCT/JP2016/003786

§ 371 Date: Feb. 21, 2018

Related U.S. Application Data
(60) Provisional application No. 62/208,988, filed on Aug. 24, 2015.

(51) Int. Cl. B01J 37/02; B01J 23/89; B01J 35/00; B01J 35/06; B01J 37/14; B01J 37/34; C23C 16/40

(52) U.S. Cl. CPC B01J 37/0226; B01J 23/8926; B01J 35/0013; C23C 16/40; B01J 37/14; B01J 37/347; B01J 35/06

(57) ABSTRACT

A method for manufacturing nanoparticle decorated nanowires by a vacuum deposition system having a deposition chamber and an aggregation chamber connected thereto includes: mounting a metal member in the deposition chamber; performing thermal oxidization of the metal member in the deposition chamber in an oxygen atmosphere so as to grow metal oxide nanowires on a surface of the metal member; without breaking vacuum in the vacuum deposition system, generating a vapor of a catalytic metal particles clusters in the aggregation chamber that is connected to the deposition chamber; and without breaking vacuum in the vacuum deposition system, transporting the generated catalytic metal particles clusters to the deposition chamber so as to decorate the metal oxide nanowires with catalytic metal nanoparticles made of the catalytic metal particles.

### TECHNICAL FIELD

The present invention relates to metal oxide nanowires decorated with nanoparticles.

This application hereby incorporates by reference U.S. Provisional Application No. 62/208,988, filed Aug. 24, 2015, in its entirety.

### BACKGROUND ART

Nanoparticle-decorated nanowires have been investigated for a variety of applications, such as gas sensor devices (NPL Nos. 1 and 2), surface-enhanced Raman scattering for chemical and biological sensing (NPL Nos. 3 and 4), Li-ion battery anodes (NPL Nos. 5 and 6) or efficient solar-energy conversion (NPL Nos. 7 and 8). In the field of conductometric gas sensors, nanoparticles are deposited on nanowire surfaces in order to improve sensor performance in terms of gas sensitivity as well as selectivity (NPL No. 9). Nanowires decorated with different catalytic nanoparticles were found to be ideally suited for the realization of miniaturized electronic nose devices, which are able to distinguish between multiple target gases (NPL No. 10). Various methods have been reported for nanoparticle decoration. For example, physical vapor deposition (NPL Nos. 11 and 12), wet-chemical methods (NPL Nos. 13 and 14), atomic layer deposition (NPL No. 15), aerosol assisted chemical vapor deposition (NPL No. 16) and γ-ray radiolysis (NPL No. 17) have been reported. Recently, the present inventors' research group demonstrated gas sensor devices based on nanoparticle-ex situ decorated CuO nanowires using magnetron sputter inert gas aggregation for nanoparticle deposition (NPL No. 18). This versatile method allows the deposition of single or multi-component nanoparticles with adjustable size, microstructure and crystallinity (NPL Nos. 19, 20, and 21), and is suitable for the synthesis of monometallic, bi-metallic, tri-metallic and alloy nanoparticles of a large variety of catalytic materials such as Pd, Pt, Ni, Ag, Fe, Cu, Ti, Si, Ge and Au.

### CITATION LIST

### Non Patent Literature

NPL 1: A. Kolmakov, D. O. Klenov, Y. Lilach, S. Stemmer, and M. Moskovits, Nano Letters 5 667-73 (2005).

NPL 2: X. Zou, J. Wang, X. Liu, C. Wang, Y. Jiang, Y. Wang, X. Xiao, J. C. Ho, J. Li, C. Jiang, Y. Fang, W. Liu, and L. Liao, Nano Letters 13 3287-92 (2013).

NPL 3: M.-L. Zhang, X. Fan, H.-W. Zhou, M.-W. Shao, J. A. Zapien, N.-B. Wong, and S.-T. Lee, Journal of Physical Chemistry C 114 1969-75 (2010).

NPL 4: X. Han, H. Wang, X. Oua, and X. Zhang, Journal of Materials Chemistry 22 14127 (2012).

NPL 5: P. Meduri, C. Pendyala, V. Kumar, G. U. Sumanasekera, and M. K. Sunkara, Nano Letters 9 612-6 (2009).

NPL 6: L. Hu, H. Wu, S. S. Hong, L. Cui, J. R. McDonough, S. Bohy, and Yi Cui, Chemical Communications 47 367-369 (2011).

NPL 7: K. S. Leschkies, R. Divakar, J. Basu, E. Enache-Pommer, J. E. Boercker, C. B. Carter, U. R. Kortshagen, D. J. Norris, and E. S. Aydil, Nano Letters 7 1793-8 (2007).

NPL 8: K.-Q. Peng, X. Wang, X.-L. Wu, and S.-T. Lee, Nano Letters 9 3704-9 (2009).

NPL 9: M. E. Franke, T. J. Koplin, and U. Simon, Small 2 36-50 (2006).

NPL 10: J. M. Baik, M. Zielke, M. H. Kim, K. L. Turner, A. M. Wodtke, and M. Moskovits, ACS Nano 4 3117-3122 (2010).

NPL 11: S. S. Kim, J. Y. Park, S.-W. Choi, H. S. Kim, H. G. Na, J. C. Yang, and H. W. Kim, Nanotechnology 21 415502 (2010).

NPL 12: I.-S. Hwang, J.-K. Choi, H.-S. Woo, S.-J. Kim, S.-Y. Jung, T.-Y. Seong, I.-D. Kim, and J.-H. Lee, ACS Applied Materials & Interfaces 3 3140-5 (2011).

NPL 13: R. K. Joshi, Q. Hu, F. Alvi, N. Joshi, and A. Kumar, Journal of Physical Chemistry C 113 16199-202 (2009).

NPL 14: X. Liu, J. Zhang, T. Yang, X. Guo, S. Wu, and S. Wang, Sensors and Actuators B: Chemical 156 918-23 (2011).

NPL 15: Y.-H. Lin, Y.-C. Hsueh, P.-S. Lee, C.-C. Wang, J. M. Wu, T.-P. Perng, and H. C. Shih, Journal of Materials Chemistry 21 10552-8 (2011).

NPL 16: S. Vallejos, T. Stoycheva, P. Umek, C. Navio, R. Snyders, C. Bittencourt, E. Llobet, C. Blackman, S. Moniz, and X. Correig, Chemical Communications 47 565-7 (2011).

NPL 17: S.-W. Choi, S.-H. Jung, S. S. and Kim, Nanotechnology 22 225501 (2011).

NPL 18: S. Steinhauer, V. Singh, C. Cassidy, C. Gspan, W. Grogger, M. Sowwan, and A. Koeck, Nanotechnology 26 175502 (2015).

NPL 19: C. Cassidy, V. Singh, P. Grammatikopoulos, F. Djurabekova, K. Nordlund, and M. Sowwan Scientific Reports 3 3083 (2013).

NPL 20: M. Benelmekki, M. Bohra, J.-H. Kim, R. E. Diaz, J. Vernieres, P. Grammatikopoulos, and M. Sowwan Nanoscale 6 3532-5 (2014).

NPL 21: V. Singh, C. Cassidy, P. Grammatikopoulos, F. Djurabekova, K. Nordlund, and M. Sowwan Journal of Physical Chemistry C 118 13869-75 (2014).

NPL 22: S. Ren, Y. F. Bal, J. Chen, S. Z. Deng, N. S. Xu, Q. B. Wu, and S. Yang, Materials Letters 61 666-70 (2007).

NPL 23: P. Hiralal, H. E. Unalan, K. G. U. Wijayantha, A. Kursumovic, D. Jefferson, J. L. MacManus-Driscoll, and G. A. J. Amaratunga, Nanotechnology 19 455608 (2008).

NPL 24: X. Jiang, T. Herricks, and Y. Xia, Nano Letters 2 1333-8 (2002).

NPL 25: S. Steinhauer, E. Brunet, T. Maier, G. C. Mutinati, and A. Koeck, Sensors and Actuators B: Chemical 186 550-6 (2014).

NPL 26: S. Steinhauer, T. Maier, G. C. Mutinati, K. Rohracher, J. Siegert, F. Schrank, and A. Koeck, Proceedings of TechConnect World Nanotech, Washington, D.C., USA. ISBN: 978-1-4822-5827-1, pp.53-56 (2014).

### SUMMARY OF INVENTION

### Technical Problem

However ex-situ deposition on pre-grown nanowires, described above, faces contamination issues that compromise the contact between the particles and the nanowires.

An object of the present invention is to provide an efficient and controlled method for in-situ growth of metal oxide nanowires and decoration of the nanowires with nanoparticles and to provide a sensor utilizing such nanoparticles decorated nanowires.

### Solution to Problem

To achieve these and other advantages and in accordance with the purpose of the present invention, as embodied and broadly described, in one aspect, the present invention provides a method for manufacturing nanoparticle decorated nanowires by a vacuum deposition system having a deposition chamber and an aggregation chamber connected thereto, the method including: mounting a metal member in the deposition chamber; performing thermal oxidization of the metal member in the deposition chamber in an oxygen atmosphere so as to grow metal oxide nanowires on a surface of the metal member; without breaking vacuum in the vacuum deposition system, generating a vapor of a catalytic metal particles clusters in the aggregation chamber that is connected to the deposition chamber; and without breaking vacuum in the vacuum deposition system, transporting the generated catalytic metal particles clusters to the deposition chamber so as to decorate the metal oxide nanowires with catalytic metal nanoparticles made of the catalytic metal particles.

Here, the metal member may be a Cu wire or a Cu foil and metal oxide nanowires may be CuO nanowires.

Alternatively, the metal member may be a pair of Cu patterns, separated from each other with a gap therebetween, formed on a Si substrate, and the step of performing thermal oxidation may grow CuO nanowires that bridge said gap between the pair of the Cu patterns on the substrate.

The catalytic metal nanoparticles may include Pd nanoparticles.

The catalytic metal nanoparticles may include Ni/Pd bimetallic nanoparticles.

The vapor of the catalytic metal particles clusters may be generated in the aggregation chamber by linear magnetron sputtering.

In another aspect, the present invention provides a method for manufacturing a sensor device by a vacuum deposition system having a deposition chamber and an aggregation chamber connected thereto, the method including: forming a pair of metallic patterns on a substrate, the metallic patterns facing each other with respective edges parallel to each other with a constant gap therebetween; mounting said substrate having the pair of metallic patterns thereon in the deposition chamber; performing thermal oxidization of the metallic patterns in the deposition chamber in an oxygen atmosphere so as to grow metal oxide nanowires bridging the gap between the pair of metallic patterns; without breaking vacuum in the vacuum deposition system, generating a vapor of a catalytic metal particles clusters in the aggregation chamber that is connected to the deposition chamber; and without breaking vacuum in the vacuum deposition system, transporting the generated catalytic metal particles clusters to the deposition chamber so as to decorate the metal oxide nanowires with catalytic metal nanoparticles made of the catalytic metal particles.

Here, the metallic patterns may be made of Cu, and metal oxide nanowires may be CuO nanowires.

### Advantageous Effects of Invention

According to one or more aspects of the present invention, nanoparticles decorated nanowires can be manufactured in a process compatible with CMOS fabrication process. Moreover, dimensions and properties of the nanoparticles decorating the nanowires are controlled by appropriately adjusting manufacturing conditions.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

It is to be understood that both the foregoing general description and the following detailed description are exemplary and explanatory, and are intended to provide further explanation of the invention as claimed.

### BRIEF DESCRIPTION OF DRAWINGS

FIG. 1 shows an experimental setup used for in situ growth and catalytic nanoparticle decoration of metal oxide nanowires. Monometallic, bi-metallic, tri-metallic and alloy nanoparticles of large veracity of materials such as Pd, Pt, Ni, Ag, Fe, Cu, Ta, Ru, Mo, Ti, Co, Si, Ge, Au, etc. can be utilized.

FIG. 2 shows TEM images of a) CuO nanowires grown by in-situ thermal oxidation of a Cu wire and b) Nanoparticle-decorated CuO nanowire surface.

FIG. 3 shows TEM images of nanoparticle-decorated CuO nanowire surfaces after in-situ growth and deposition of a) Pd nanoparticles and b) bi-metallic Ni/Pd nanoparticles.

FIG. 4 shows: a) a low-magnification SEM image of an electrical device based on nanoparticle-decorated CuO nanowires (the inset shows room temperature IV characteristics); b) a SEM image of CuO nanowires bridging the gap between adjacent oxidized Cu structures forming an electrical connection; and c) a high resolution SEM image of nanoparticle-decorated CuO nanowire.

### DESCRIPTION OF EMBODIMENTS

The present disclosure provides a novel method for in-situ metal oxide nanowire growth and decoration with catalytic nanoparticles inside a CMOS compatible nanoparticle deposition system. The present disclosure presents results on CuO nanowires decorated with monometallic nanoparticles (Pd) and bimetallic nanoparticles (PdNi). It is believed that this technology can be used for different types of metal oxide nanowires synthesized by thermal oxidation, such as ZnO (NPL No. 22) or Fe₂O₃ (NPL No. 23). Furthermore, the present disclosure shows the in-situ realization of nanoparticle-decorated CuO nanowire devices on Si substrates, which is a crucial step towards the development of smart electronic nose systems, for example.

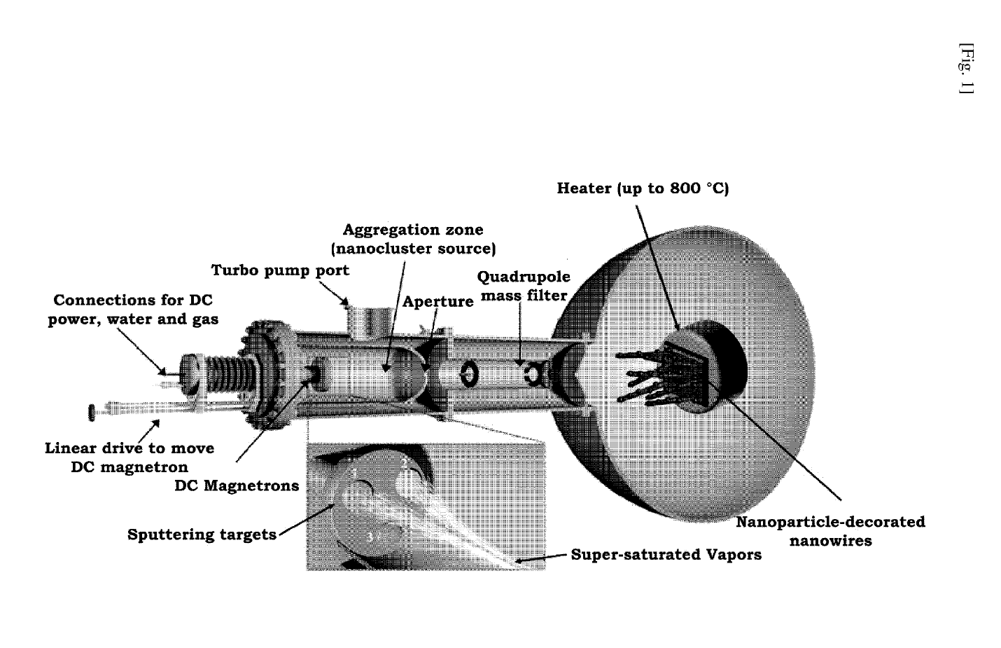

In-situ CuO nanowire growth and nanoparticle decoration were performed in a modified ultra-high vacuum deposition system with a magnetron-sputtering inert gas-condensation cluster beam source as illustrated in FIG. 1. FIG. 1 shows an experimental setup used for in situ growth and catalytic nanoparticle decoration of metal oxide nanowires. Monometallic, bi-metallic, tri-metallic and alloy nanoparticles of large veracity of materials such as Pd, Pt, Ni, Ag, Fe, Cu, Ta, Ru, Mo, Ti, Co, Si, Ge, Au, etc. can be utilized. As shown in FIG. 1, the disclosed process generally includes: mounting a metal member in the deposition chamber; performing thermal oxidization of the metal member in the deposition chamber in an oxygen atmosphere so as to grow metal oxide nanowires on a surface of the metal member; without breaking vacuum in the vacuum deposition system, generating a vapor of a catalytic metal particles clusters in the aggregation chamber that is connected to the deposition chamber; and without breaking vacuum in the vacuum deposition system, transporting the generated catalytic metal particles clusters to the deposition chamber so as to decorate the metal oxide nanowires with catalytic metal nanoparticles made of the catalytic metal particles. In this embodiment, a highly pure Cu wire (Alfa Aesar, diameter 100 μm, 6N) was mounted in the deposition chamber and used as substrate for CuO nanowire growth. Thermal oxidation experiments were carried out at an oxygen pressure around 25 mbar and a sample heater setpoint temperature of 600° C. for 60 min. Nanoparticles were deposited after the heating stage cooled down to around 200° C. at a pressure of approximately 8×10⁴ mbar.

The fabrication of nanoparticle-decorated CuO nanowire devices comprised the following steps: Two subsequent photolithographic lift-off processes were performed on Si substrates covered with 50 nm of thermal SiO₂ in order to structure electron beam evaporated layers of Ti/Au (contact electrodes; thickness around 5 nm and 200 nm, respectively) and Ti/Cu (substrate for CuO nanowire growth; thickness around 5 nm and 650 nm, respectively). Samples were loaded into the nanoparticle deposition system and oxygen was introduced until a constant pressure of 1000 mbar was reached. Thermal oxidation was performed at a sample heater setpoint temperature of 650° C. for 120 min. The samples were decorated with nanoparticles after the heating stage cooled down to around 100° C. at a pressure of approximately 8×10⁴ mbar. Nanoparticles were deposited using an aggregation length of 100 mm and an Ar pressure of 2.5×10⁻¹ mbar in the aggregation zone. Magnetron powers of 15W and 40W were applied for sputtering of Pd and Ni targets, respectively.

Nanoparticle-decorated CuO nanowire samples were imaged with a FEI Titan G2 environmental transmission electron microscope (TEM) equipped with a spherical aberration image corrector and a FEI Helios G3 UC scanning electron microscope (SEM). Electrical measurements were performed using tip probe station and a Keithley 2400 SourceMeter.

<Results>

<(a) In-situ CuO Nanowire Growth and Nanoparticle Decoration>

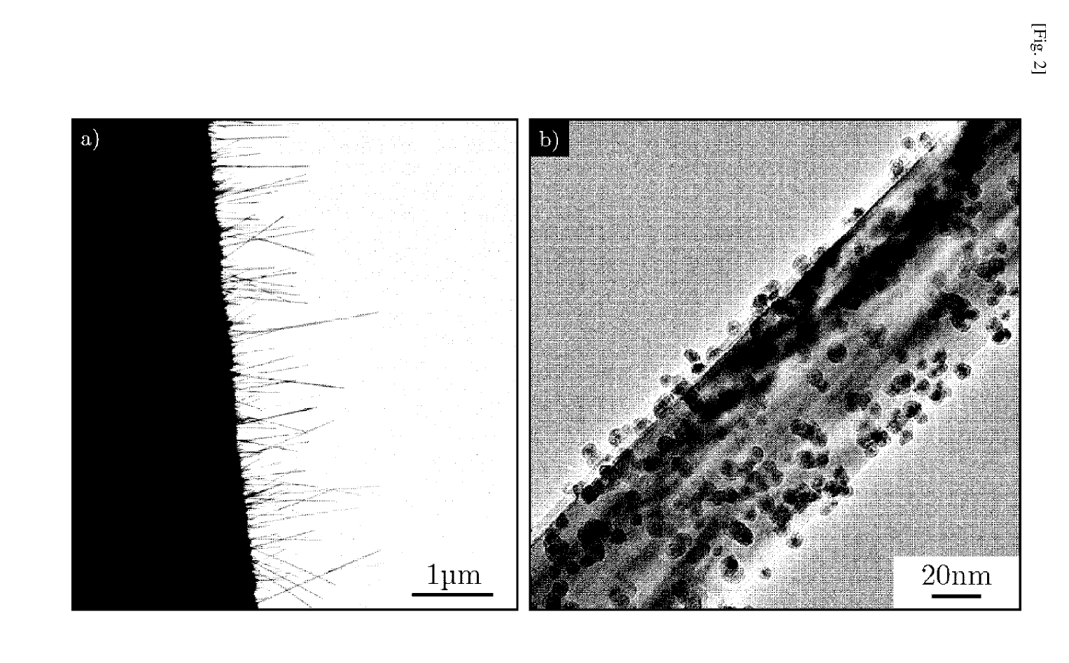

The heat treatment in oxygen atmosphere inside the magnetron sputter gas aggregation system resulted in thermal oxidation of the Cu wire and CuO nanowire growth. FIG. 2a) shows a low magnification TEM image of the sample surface covered with nanoparticle-decorated CuO nanowires. Our in-situ growth results are well comparable in terms of size and crystallinity with literature reports on CuO nanowire synthesis in air (NPL No. 24). As can be seen in FIG. 2b), the CuO nanowire surfaces were successfully decorated with nanoparticles after the magnetron sputter gas aggregation deposition.

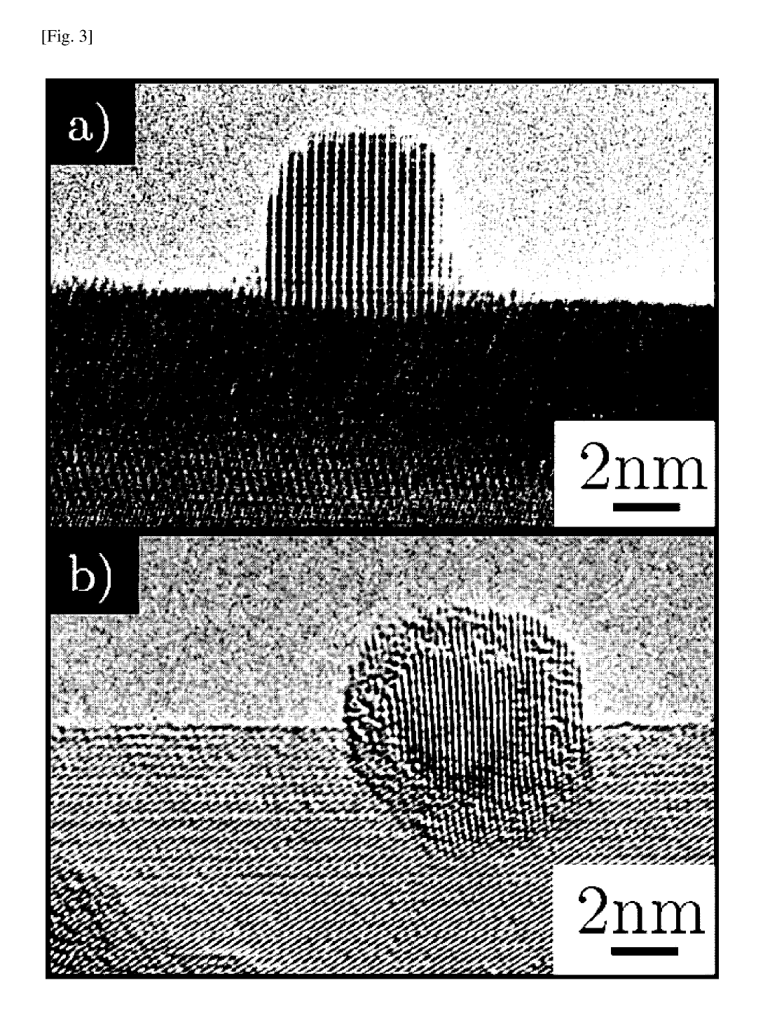

Due to the high degree of deposition parameter control, magnetron sputter gas aggregation is able to produce nanoparticles with well-defined size and structure of a large variety of different materials (NPL Nos. 18, 19, 20, and 21). FIGS. 3a) and b) show nanoparticle-decorated CuO nanowire surfaces after in-situ growth and deposition of Pd and bi-metallic Ni/Pd nanoparticles, respectively. As is known from literature (NPL No. 9), the gas sensitivity as well as selectivity of metal oxide-based gas sensors can be controlled by the catalytic activity of nanoscaled surface additives. Thus the in-situ CuO nanowire growth and nanoparticle decoration results describe herein are an important step towards the efficient realization of sensor devices with specifically tailored gas response.

<(b) In-situ Realization of Nanoparticle-Decorated CuO Nanowire Devices>

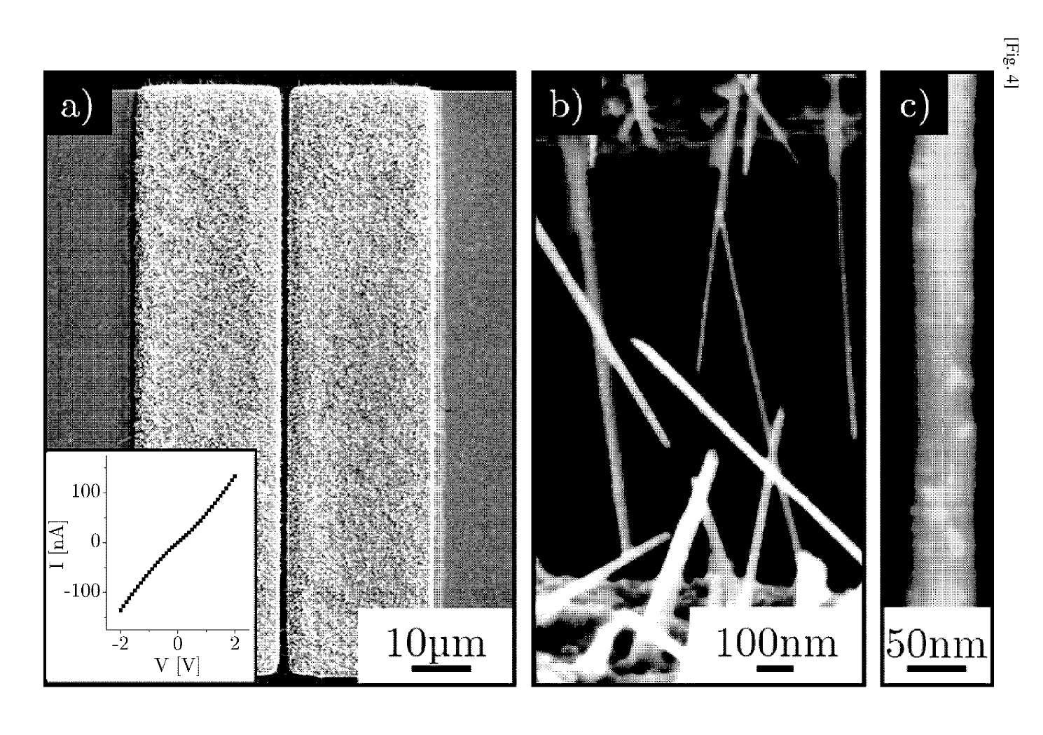

The above-described in-situ nanowire growth and nanoparticle decoration method were utilized in order to demonstrate the realization of a CuO nanowire device according to an embodiment of the present invention. In this case, Cu microstructures on a Si substrate are used for CuO nanowire growth by thermal oxidation inside the magnetron sputter gas aggregation system. A low magnification SEM image of a representative device is shown in FIG. 4a). Two Cu rectangles (side lengths 20 μm and 100 m, gap distance before thermal oxidation 2.5 μm) were connected to two Au electrodes, which can be seen on the left and right side of the image. After thermal oxidation inside the magnetron sputter gas aggregation system, the gap between the Cu rectangles was bridged by multiple CuO nanowires (FIG. 4b), which form an electrical connection between the oxidized Cu microstructures, as shown in the inset of FIG. 4a) that shows room temperature I-V characteristics. FIG. 4c) is a high resolution SEM image of nanoparticle-decorated CuO nanowire. As shown in FIG. 4c), the nanowires were successfully decorated by the nanoparticles.

A similar device design was reported in (NPL No. 25) and was found to show excellent gas sensor performance. In this disclosure, as described above, CuO nanowire-based gas sensors were demonstrated to be compatible with standard CMOS technology, which is of crucial importance for future integrated, miniaturized sensor devices (NPL No. 26). The presented method enables in-situ CuO nanowire growth and nanoparticle decoration, which allows the efficient fabrication of nanoparticle-decorated sensor devices with minimized surface contamination. As magnetron sputter gas aggregation is a versatile technique for the deposition of various different catalytic nanoparticles, our technology is suitable for the realization of nanoparticle-based smart electronic nose systems.

Thus, the present disclosure provides in-situ CuO nanowire growth and nanoparticle decoration inside a magnetron sputter gas aggregation system. This method allows nanoparticle decoration with a large variety of nanoparticle materials and enables the efficient realization of electronic devices based on nanoparticle-decorated CuO nanowires. Our fabrication technology is ideally suited for the future development of miniaturized, smart electronic nose systems based on catalytic nanoparticles with well-defined size and structure.

It will be apparent to those skilled in the art that various modification and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

1. A method for manufacturing nanoparticle decorated nanowires by a vacuum deposition system having a deposition chamber and an aggregation chamber connected thereto, the method comprising:
mounting a metal member in the deposition chamber;
performing thermal oxidization of the metal member in the deposition chamber in an oxygen atmosphere so as to grow metal oxide nanowires on a surface of the metal member;
without breaking vacuum in the vacuum deposition system, generating a vapor of a catalytic metal particles clusters in the aggregation chamber that is connected to the deposition chamber; and
without breaking vacuum in the vacuum deposition system, transporting the generated catalytic metal particles clusters to the deposition chamber so as to decorate the metal oxide nanowires with catalytic metal nanoparticles made of the catalytic metal particles.

2. The method according to claim 1, wherein the metal member is a Cu wire, and metal oxide nanowires are CuO nanowires.

3. The method according to claim 1,
wherein the metal member is a pair of Cu patterns, separated from each other with a gap therebetween, formed on a Si substrate, and
wherein the step of performing thermal oxidation grows CuO nanowires that bridge said gap between the pair of the Cu patterns on the substrate.

4. The method according to claim 1, wherein the catalytic metal nanoparticles include Pd nanoparticles.

5. The method according to claim 1, wherein the catalytic metal nanoparticles include Ni/Pd bimetallic nanoparticles.

6. The method according to claim 1,
wherein the metal member is a Cu wire, and metal oxide nanowires are CuO nanowires, and
wherein the catalytic metal nanoparticles include Pd nanoparticles.

7. The method according to claim 1,
wherein the metal member is Cu wire, and metal oxide nanowires are CuO nanowires, and
wherein the catalytic metal nanoparticles include Ni/Pd nanoparticles.

8. The method according to claim 1, wherein the vapor of the catalytic metal particles clusters is generated in the aggregation chamber by linear magnetron sputtering.

9. A method for manufacturing a sensor device by a vacuum deposition system having a deposition chamber and an aggregation chamber connected thereto, the method comprising:
forming a pair of metallic patterns on a substrate, the metallic patterns facing each other with respective edges parallel to each other with a constant gap therebetween;
mounting said substrate having the pair of metallic patterns thereon in the deposition chamber;
performing thermal oxidization of the metallic patterns in the deposition chamber in an oxygen atmosphere so as to grow metal oxide nanowires bridging the gap between the pair of metallic patterns;
without breaking vacuum in the vacuum deposition system, generating a vapor of a catalytic metal particles clusters in the aggregation chamber that is connected to the deposition chamber; and
without breaking vacuum in the vacuum deposition system, transporting the generated catalytic metal particles clusters to the deposition chamber so as to decorate the metal oxide nanowires with catalytic metal nanoparticles made of the catalytic metal particles.

10. The method according to claim 9, wherein the metallic patterns are made of Cu, and metal oxide nanowires are CuO nanowires.

11. The method according to claim 9, wherein the catalytic metal nanoparticles include Pd nanoparticles.

12. The method according to claim 9, wherein the catalytic metal nanoparticles include Ni/Pd bimetallic nanoparticles.

13. The method according to claim 9, wherein the metallic patterns are made of Cu, and metal oxide nanowires are CuO nanowires, and wherein the catalytic metal nanoparticles include Pd nanoparticles.

14. The method according to claim 9, wherein the metallic patterns are made of Cu, and metal oxide nanowires are CuO nanowires, and wherein the catalytic metal nanoparticles include Ni/Pd nanoparticles.

15. The method according to claim 9, wherein the vapor of the catalytic metal particles clusters is generated in the aggregation chamber by linear magnetron sputtering.

16. The method according to claim 9, wherein the substrate is a Si substrate.
